(19) United States
(12) Patent Application Publication
(10) Pub. No.: US 2009/0229662 A1
(43) Pub. Date: Sep. 17, 2009

(54) Off-Cut Substrates In Inverted Metamorphic Multijunction Solar Cells

(75) Inventors: Mark A. Stan, Albuquerque, NM (US); Allen L. Gray, Albuquerque, NM (US); Arthur Cornfeld, Sandia Park, NM (US); Fred Newman, Albuquerque, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/047,944

(22) Filed: Mar. 13, 2008

(51) Int. Cl. H01L 31/0264; H01L 31/18; H01L 31/042

(52) U.S. Cl. 136/261; 438/73; 136/262; 257/E31.004

(57) ABSTRACT

A method of forming a multijunction solar cell including an upper subcell, a middle subcell, and a lower subcell, including: providing a substrate having an off-cut of 15° from the (001) plane to the (111)A plane for the epitaxial growth of semiconductor material; forming a first solar subcell on the substrate having a first band gap; forming a second solar subcell over the first solar subcell having a second band gap smaller than the first band gap; forming a grading interlayer over the second subcell layer, the grading interlayer having a third band gap greater than the second band gap; and forming a third solar subcell over the grading interlayer having a fourth band gap smaller than the second band gap such that the third subcell is lattice mismatched with respect to the second subcell.

### REFERENCE TO RELATED APPLICATIONS

This application is related to co-pending U.S. patent application Ser. No. 12/023,772, filed Jan. 31, 2008.

This application is related to co-pending U.S. patent application Ser. No. 11/956,069, filed Dec. 13, 2007.

This application is also related to co-pending U.S. patent application Ser. Nos. 11/860,142 and 11/860,183 filed Sep. 24, 2007.

This application is also related to co-pending U.S. patent application Ser. No. 11/836,402 filed Aug. 8, 2007.

This application is also related to co-pending U.S. patent application Ser. No. 11/616,596 filed Dec. 27, 2006.

This application is also related to co-pending U.S. patent application Ser. No. 11/614,332 filed Dec. 21, 2006.

This application is also related to co-pending U.S. patent application Ser. No. 11/500,053 filed Aug. 7, 2006.

This application is also related to co-pending U.S. patent application Ser. No. 11/445,793 filed Jun. 2, 2006.

### GOVERNMENT RIGHTS STATEMENT

This invention was made with government support under Contract No. FA9453-06-C-0345 awarded by the U.S. Air Force. The Government has certain rights in the invention.

### BACKGROUND OF THE INVENTION

1. Field of the Invention

The present invention relates to the field of solar cell semiconductor devices, and to multifunction solar cells based on III-V semiconductor compounds including a metamorphic layer. More particularly, the invention relates to fabrication processes and devices also known as inverted metamorphic solar cells.

2. Description of the Related Art

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as satellites used in data communications have dramatically increased the demand for solar cells with improved power and energy conversion characteristics.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as the payloads become more sophisticated, solar cells, which act as the power conversion devices for the on-board power systems, become increasingly more important.

Solar cells are often fabricated in vertical, multifunction structures, and disposed in horizontal arrays, with the individual solar cells connected together in a series. The shape and structure of an array, as well as the number of cells it contains, are determined in part by the desired output voltage and current.

Inverted metamorphic solar cell structures such as described in M. W. Wanless et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005) present an important starting point for the development of future commercial high efficiency solar cells. The structures described in such prior art present a number of practical difficulties relating to the appropriate choice of materials and fabrication steps, in particular associated with the lattice mismatched layers between the “lower” subcell (the subcell with the lowest band gap) and the adjacent subcell.

A multi-junction solar cell of the type described by Wanlass, having an upper subcell, middle subcell and a lower subcell, includes a metamorphic buffer layer of InGaP between the last two subcells formed on the growth substrate. In the process of developing such a metamorphic buffer layer and the last subcell, it has been found that severe morphology issues occur in connection with the 2° off-cut GaAs substrate used by Wanlass at the usual growth temperature of 620° C., even though the metamorphic buffer layer appears to grow two dimensionally. At a higher growth temperature of 660° C., the morphology was not significantly improved. Moreover, although the Wanlass method yields operational triple junction solar cells, the fabrication processes associated with this method requires a large flow of phosphine in the MOCVD reactor, which is not necessarily desirable for many growth systems or high volume production.

Prior to the present invention, the materials and fabrication steps disclosed in the prior art have not been adequate to produce a commercially viable and energy efficient solar cell using commercially established fabrication processes for producing an inverted metamorphic multijunction cell structure.

### SUMMARY OF THE INVENTION

Briefly, and in general terms the invention provides a method of forming a multifunction solar cell comprising an upper subcell, a middle subcell, and a lower subcell, by providing a first substrate for the epitaxial growth of semiconductor material which is off-cut from the (001) plane by at least 6° towards the (111)A plane direction; forming a first solar subcell on the off-cut substrate having a first band gap; forming a second solar subcell over the first solar subcell having a second band gap smaller than the first band gap; forming a grading interlayer over the second solar cell, the grading interlayer having a third band gap greater than the second band gap; and forming a third solar subcell over the grading interlayer having a fourth band gap smaller than the second band gap such that the third subcell is lattice mismatched with respect to the second subcell.

In another aspect, the invention also provides a method of manufacturing a solar cell by providing a first sequence of layers of semiconductor material forming a solar cell, on a substrate having an off-cut of at least 6°; mounting a surrogate substrate on top of the sequence of layers; and removing the first substrate.

In another aspect, the present invention provides a multifunction solar cell including a semiconductor substrate which is off-cut from a crystal plane by at least 6°; a first solar subcell formed on the substrate having a first band gap; a second solar subcell disposed over the first subcell and having a second band gap smaller than the first band gap; a grading interlayer disposed over the second solar subcells and having a third band gap greater than said second band gap; and a third solar subcell disposed over said grading interlayer that is lattice mismatched with respect to said middle subcell and having a fourth band gap smaller than said third band gap.

In another aspect, the present invention provides a photovoltaic solar cell comprising a top cell including base and emitter layers composed of InGaP semiconductor material, grown on a GaAs substrate having an off-cut from the (001) plane by at least 6° in the direction of the (111)A plane.

### BRIEF DESCRIPTION OF THE DRAWINGS

The invention will be better and more fully appreciated by reference to the following detailed description when considered in conjunction with the accompanying drawings, wherein:

FIG. 1A is a perspective view of a polyhedral representation of a semiconductor lattice structure showing the crystal planes;

FIG. 1B is a perspective view of the GaAs crystal lattice showing the position of the gallium and arsenic atoms;

FIG. 2A is a perspective view of the plane of the substrate employed in the present invention superimposed over the crystal diagram of FIG. 1;

FIG. 2B is a graphical depiction of the surface of the plane of the substrate employed in the present invention;

FIG. 3 is a graph representing the band gap of certain binary materials and their lattice constants;

FIG. 4 is a cross-sectional view of the solar cell of the invention after the deposition of semiconductor layers on the growth substrate;

FIG. 5 is a cross-sectional view of the solar cell of FIG. 4 after the next process step;

FIG. 6 is a cross-sectional view of the solar cell of FIG. 5 after next process step;

FIG. 7 is a cross-sectional view of the solar cell of FIG. 6 after the next process step;

FIG. 8A is a cross-sectional view of the solar cell of FIG. 7 after the next process step in which the original substrate is removed;

FIG. 8B is another cross-sectional view of the solar cell of FIG. 8A with the surrogate substrate on the bottom of the Figure;

FIG. 9 is a simplified cross-sectional view of the solar cell of FIG. 8B;

FIG. 10 is a cross-sectional view of the solar cell of FIG. 9 after the next process step;

FIG. 11 is a cross-sectional view of the solar cell of FIG. 10 after the next process step;

FIG. 12 is a cross-sectional view of the solar cell of FIG. 11 after the next process step;

FIG. 13A is a top plan view of a wafer in which the solar cells are fabricated;

FIG. 13B is a bottom plan view of a wafer in which the solar cells are fabricated;

FIG. 14 is a cross-sectional view of the solar cell of FIG. 12 after the next process step;

FIG. 15 is a cross-sectional view of the solar cell of FIG. 14 after the next process step;

FIG. 16 is a top plan view of the wafer of FIG. 15 depicting the trench etched around each of the solar cells;

FIG. 17A is a cross-sectional view of the solar cell of FIG. 15 after the next process step in a first embodiment of the present invention;

FIG. 17B is a cross-sectional view of the solar cell of FIG. 15 after the next process step in a second embodiment of the present invention;

FIG. 18 is a cross-sectional view of the solar cell of FIG. 15 after the next process step in a third embodiment of the present invention; and

FIG. 19 is a graph of the doping profile in a base layer in the metamorphic solar cell according to the present invention.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale

The basic concept of fabricating an inverted metamorphic multijunction (IMM) solar cell is to grow the subcells of the solar cell on a substrate in a “reverse” sequence. That is, the high bandgap subcells (i.e. subcells with bandgaps in the range of 1.8 to 2.2 eV), which would normally be the “top” subcells facing the solar radiation, are grown epitaxially on a semiconductor growth substrate, such as for example GaAs or Ge, and such subcells are therefore lattice-matched to such substrate. One or more lower bandgap middle subcells (i.e. with bandgaps in the range of 1.2 to 1.6 eV and 0.8 to 1.2 eV) can then be grown on the high bandgap subcells.

At least one lower subcell is formed over the middle subcell such that the at least one lower subcell is substantially lattice-mismatched with respect to the growth substrate and such that the at least one lower subcell has a third lower bandgap (i.e. a bandgap in the range of 0.8 to 1.2 eV). A surrogate substrate or support structure is provided over the “bottom” or substantially lattice-mismatched lower subcell, and the growth semiconductor substrate is subsequently removed. (The growth substrate may then subsequently be re-used for the growth of a second and subsequent solar cells).

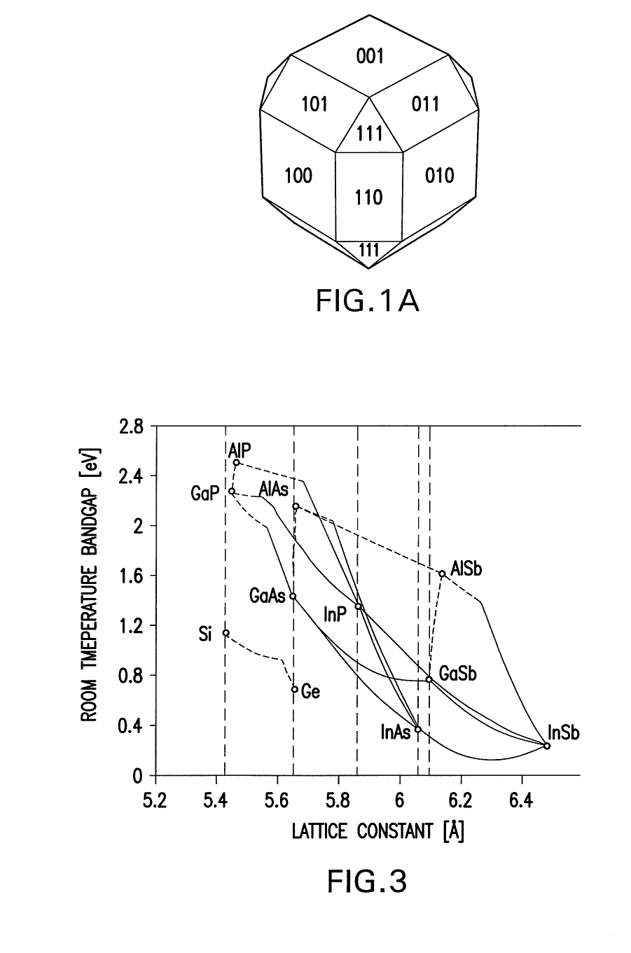

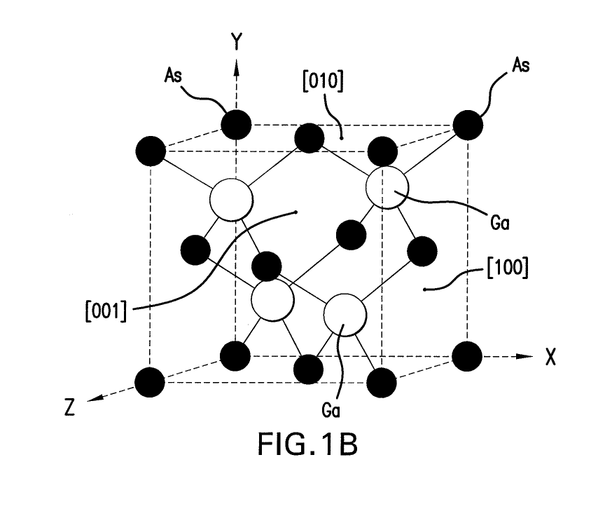

FIG. 1A is a perspective view of a polyhedral representation of a semiconductor lattice structure showing the crystal planes. The Miller indices are used to identify the planes, and the crystal structure is represented in the Figure by a truncated cube with the (001) plane at the top. In the case of a GaAs compound semiconductor, which is the material of interest in the present invention, the crystal structure is known as the zinc blended structure, and is shown in FIG. 1B, which represents a combination of twointerpenetrating face centered cubic sublattices. The lattice constant (i.e., the distance between the arsenic atoms in the crystal) is 0.565 nm.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), Molecular Beam Epitaxy (MBE), or other vapor deposition methods for the reverse growth may enable the layers in the monolithic semiconductor structure forming the cell to be grown with the required thickness, elemental composition, dopant concentration and grading and conductivity type.

FIG. 1B is a perspective view of the GaAs crystal lattice showing the position of the gallium and arsenic atoms, with the corresponding Miller indices identifying the lattice planes.

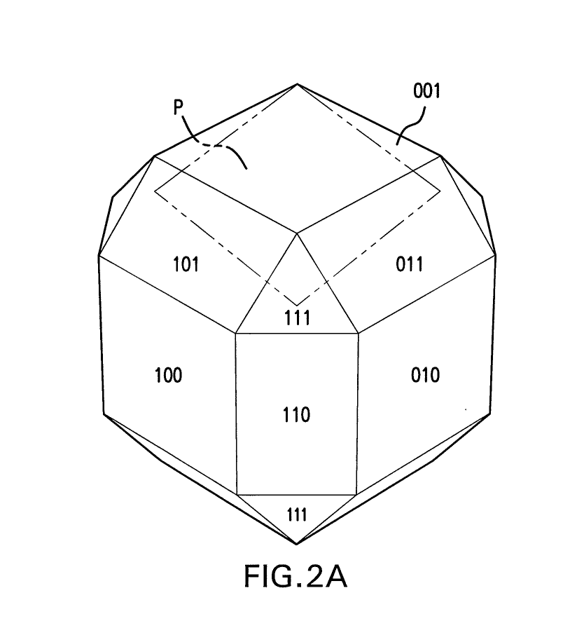

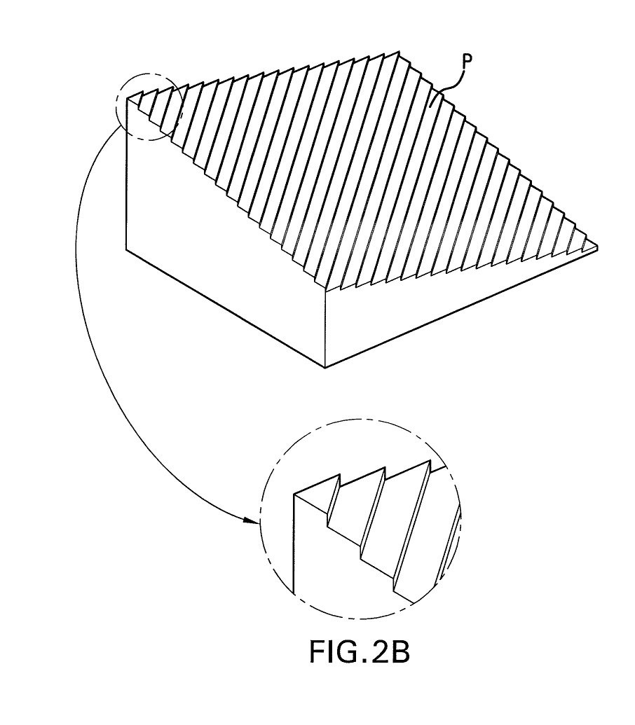

FIG. 2A is a perspective view of the plane P of the substrate surface employed in the present invention superimposed over the crystal diagram of FIG. 1A. The plane P is seen to pivot from a point on the (001) plane (in this representation, the rear corner of the top surface of the polyhedron) in the direction of the (111) plane, or more accurately the (111)A plane, where the letter “A” refers to the plane formed by the sublattice of arsenic atoms. The angle of pivot according to the present invention defines the angle of off-cut of the substrate defined from the (001) plane by the plane P, which is at least 6° and preferably approximately 15°.

Although the present invention ideally provides for an offcut in the [111]A direction, it may be that during production and fabrication of various wafer lots, the alignment or cutting process is not as precise or exacting as may be specified by the present invention, and the resulting plane P may pivot slightly in the direction of the adjacent (011) or (101) planes, as well as in the direction of the (111)A plane. Such deviations, whether inadvertent or for some other mechanical or structural reason, are contemplated to be within the scope of the present invention as well.

Thus, in the most general form, as used in the present disclosure the recitation “off-cut from the (001) crystal plane by at least 6° towards the (111)A plane” contemplates and includes the off-cut plane P pivoting towards any of the following planes:

(i) an adjacent (111)A plans by at least 6 degrees and at most 20 degrees;

(ii) an adjacent (011) plans by at most approximately one degree;

(iii) an adjacent (101) plans by at most approximately one degree; and

(iv) any plane lying in the continuum of planes between (i) and (ii), (i) and (iii), or (ii) and (iii) above.

FIG. 2B is an enlarged perspective view of an off-cut GaAs substrate showing how the off-cut results in a staircase of planar steps extending over the surface of the substrate.

FIG. 3 is a graph representing the band gap of certain binary materials and their lattice constants. The band gap and lattice constants of ternary materials are located on the lines drawn between typical associated binary materials (such as GaAlAs being between the GaAs and AlAs points on the graph, with the band gap varying between 1.42 eV for GaAs and 2.16 eV for AlAs). Thus, depending upon the desired band gap, the material constituents of a ternary materials can be appropriately selected for growth.

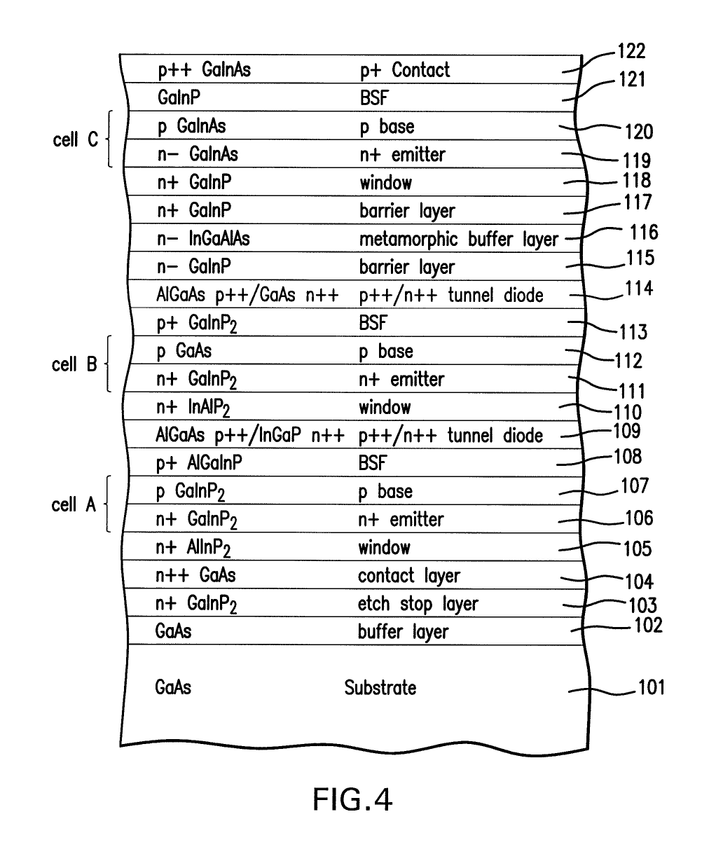

FIG. 4 depicts the multifunction solar cell according to the present invention after the sequential formation of the three subcells A, B and C on a GaAs growth substrate. More particularly, there is shown a substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111)A plane.

On the substrate, (or over the nucleation layer, if there is one), a buffer layer 102 (preferably GaAs), and an etch stop layer 103 (preferably n+GaInP) are further deposited. A cap or contact layer 104 (preferably n++ GaAs) is then deposited on layer 103, and a window layer 105 (preferably AlInP) is deposited on the contact layer. The subcell A, consisting of an n+ emitter layer 106 and a p-type base layer 107, is then epitaxilly deposited on the window layer 15, and lattice matched to the substrate 101.

It should be noted that the multijunction solar cell structure could be formed by any suitable combination of group III to V elements listed in the periodic table subject to lattice constant and band gap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorus (P), arsenic (As), antimony (Sb), and bismuth (Bi).

In the preferred embodiment, the emitter layer 106 of subcell A is composed of n+ type InGa(Al)P and the base layer 107 is composed of p type InGa(Al)P. The Al term in parenthesis means that Al is an optional constituent, and in this instance, may be used in an amount ranging from 0% to 30%.

Subcell A will ultimately become the “top” subcell of the inverted metamorphic structure after completion of the process steps according to the present invention to be described hereinafter.

On top of the base layer 107 a back surface field (“BSF”) layer 108 is deposited and used to reduce recombination loss, preferably p+ AlGaInP.

The BSF layer 108 drives minority carriers from the region near the base/BSF interface surface to minimize the effect of recombination loss. In other words, a BSF layer 108 reduces recombination loss at the backside of the solar subcell A and thereby reduces the recombination in the base.

On top of the BSF layer 108 is deposited a sequence of heavily doped p-type and n-type layers 109 which forms a tunnel diode which is an ohmic circuit element to connect subcell A to subcell B. These layers are preferably composed of p++Al GaAs, and n++InGaP.

On top of the tunnel diode layers 109 a window layer 110 is deposited, preferably n+ InAlP. The window layer 110 used in the subcell B operates to reduce the interface recombination loss. It should be apparent to one skilled in the art, that additional layer(s) may be added or deleted in the cell structure without departing from the scope of the present invention.

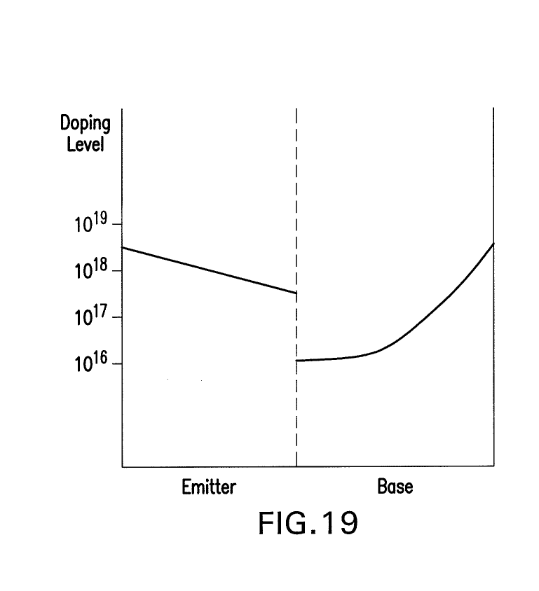

On top of the window layer 110 the layers of subcell B are deposited: the n-type emitter layer 111 and the p-type base layer 112. These layers are preferably composed of InGaP and In_{0.015}GaAs respectively (for a Ge substrate or growth template), or InGaP and GaAs respectively (for a GaAs substrate), although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The doping profile of layers 111 and 112 according to the present invention will be discussed in conjunction with FIG. 19.

On top of the cell B is deposited a BSF layer 113 which performs the same function as the BSF layer 109. A p++/n++ tunnel diode 114 is deposited over the BSF layer 113 similar to the layers 109, again forming an ohmic circuit element to connect subcell B to subcell C. These layers 114 are preferably compound of p++ Al GaAs and n++ GaAs.

A barrier layer 115, preferably composed of n-type InGa(Al)P, is deposited over the tunnel diode 114, to a thickness of about 1.0 micron. Such barrier layer is intended to prevent threading dislocations from propagating, either opposite to the direction of growth into the middle and top subcells B and C, or in the direction of growth into the bottom subcell A, and is more particularly described in copending U.S. patent application Ser. No. 11/860,183, filed Sep. 24, 2007.

A metamorphic layer (or graded interlayer) 116 is deposited over the barrier layer 115. Layer 116 is preferably a compositionally step-graded series of InGaAlAs layers, preferably with monotonically changing lattice constant, so as to achieve a gradual transition in lattice constant in the semiconductor structure from subcell B to subcell C while minimizing threading dislocations formation. The bandgap of layer 116 is constant throughout its thickness preferably approximately 1.5 eV or otherwise consistent with a value greater than the bandgap of the middle subcell B. The preferred embodiment of the graded interlayer may also be expressed as being composed of (InₓGa₁₋ₓ)_{y}Al_{1-y}As, with x and y selected such that the band gap of the interlayer remains constant at approximately 1.50 eV.

In an alternative embodiment where the solar cell has only two subcells, and the “middle” cell B is the uppermost or top subcell in the final solar cell, wherein the “top” subcell B would typically have a bandgap of 1.8 to 1.9 eV, then the band gap of the interlayer would remain constant at 1.9 eV.

In the inverted metamorphic structure described in the Wanless et al. paper cited above, the metamorphic layer consists of nine compositionally graded InGaP steps, with each step layer having a thickness of 0.25 micron. As a result, each layer of Wanless et al. has a different bandgap. In the preferred embodiment of the present invention, the layer 116 is composed of a plurality of layers of InGaAlAs, with monotonically changing lattice constant, each layer having the same bandgap, approximately 1.5 eV.

The advantage of utilizing a constant bandgap material such as InGaAlAs is that arsenide-based semiconductor material is much easier to process in standard commercial MOCVD reactors, while the small amount of aluminum assures radiation transparency of the metamorphic layers.

Although the preferred embodiment of the present invention utilizes a plurality of layers of InGaAlAs for the metamorphic layer 116 for reasons of manufacturability and radiation transparency, other embodiments of the present invention may utilize different material systems to achieve a change in lattice constant from subcell B to subcell C. Thus, the system of Wanlass using compositionally graded InGaP is a second embodiment of the present invention. Other embodiments of the present invention may utilize continuously graded, as opposed to step graded, materials. More generally, the graded interlayer may be composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

In another embodiment of the present invention, an optional second barrier layer 117 may be deposited over the InGaAlAs metamorphic layer 116. The second barrier layer 117 will typically have a different composition than that of barrier layer 115, and performs essentially the same function of preventing threading dislocations from propagating. In the preferred embodiment, barrier layer 117 is n+ type GaInP.

A window layer 118 preferably composed of n+ type GaInP is then deposited over the barrier layer 117 (or directly over layer 116, in the absence of a second barrier layer). This window layer operates to reduce the recombination loss in subcell “C”. It should be apparent to one skilled in the art that additional layers may be added or deleted in the cell structure without departing from the scope of the present invention.

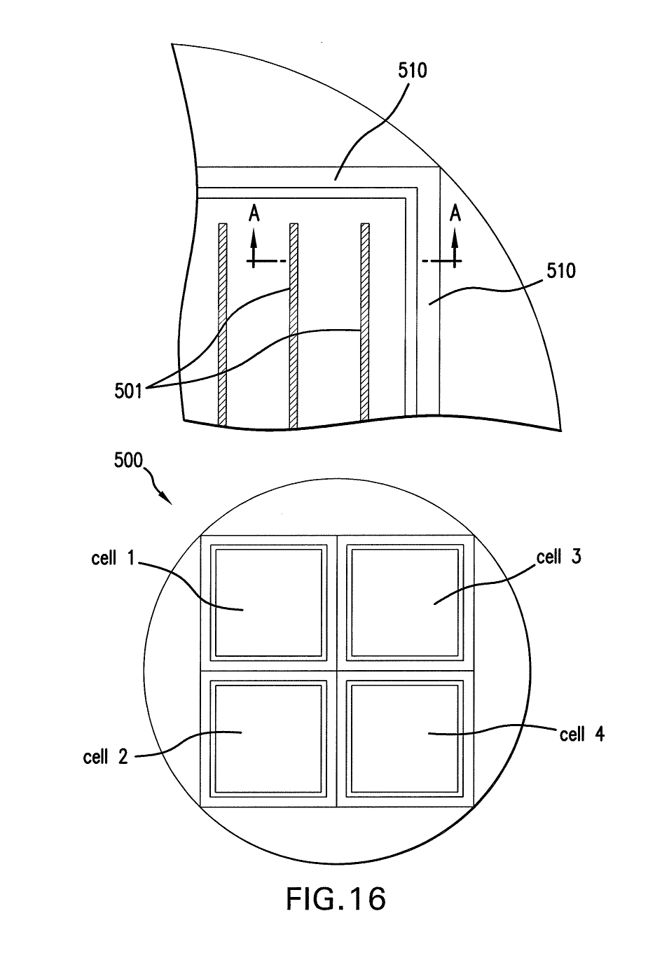

On top of the window layer 118, the layers of cell C are deposited: the n−emitter layer 119, and the p-type base layer 120. These layers are preferably composed of n type InGaAs and p type InGaAs respectively, or n type InGaP and p type InGaAs for a heterojunction subcell, although another suitable materials consistent with lattice constant and bandgap requirements may be used as well. The doping profile of layers 119 and 120 will be discussed in connection with FIG. 16.

A BSF layer 121, preferably composed of GaInP, is then deposited on top of the cell C, the BSF layer performing the same function as the BSF layers 108 and 113.

Finally a p++ contact layer 122 composed of GaInAs is deposited on the BSF layer 121.

It should be apparent to one skilled in the art, that additional layer(s) may be added or deleted in the cell structure without departing from the scope of the present invention.

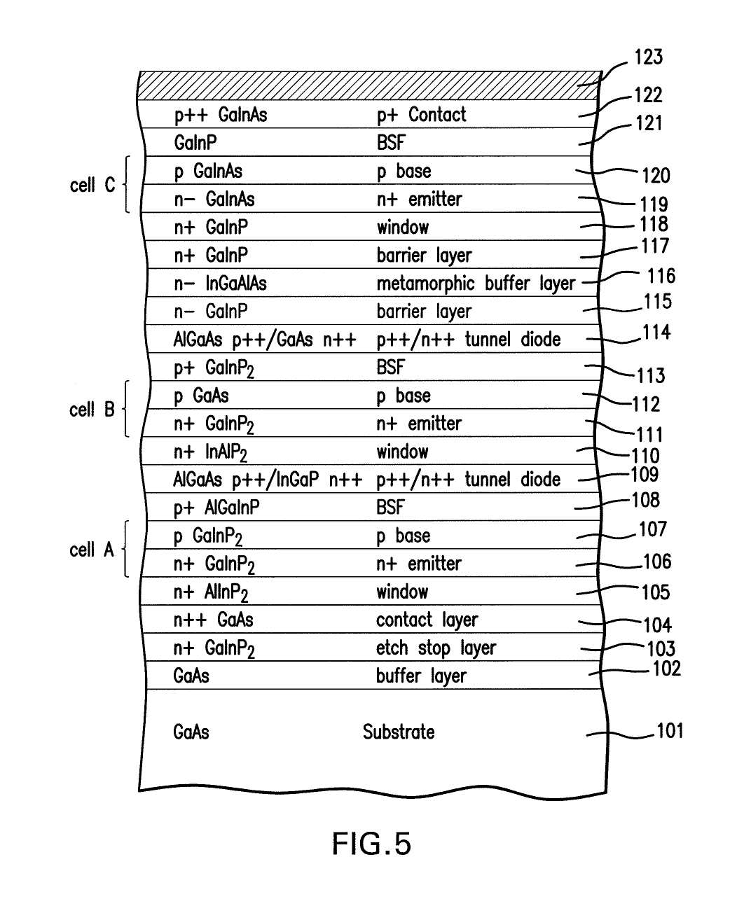

FIG. 5 is a cross-sectional view of the solar cell of FIG. 4 after the next process step in which a metal contact layer 123 is deposited over the p+semiconductor contact layer 122. The metal is preferably the sequence of metal layers Ti/Au/Ag/Au.

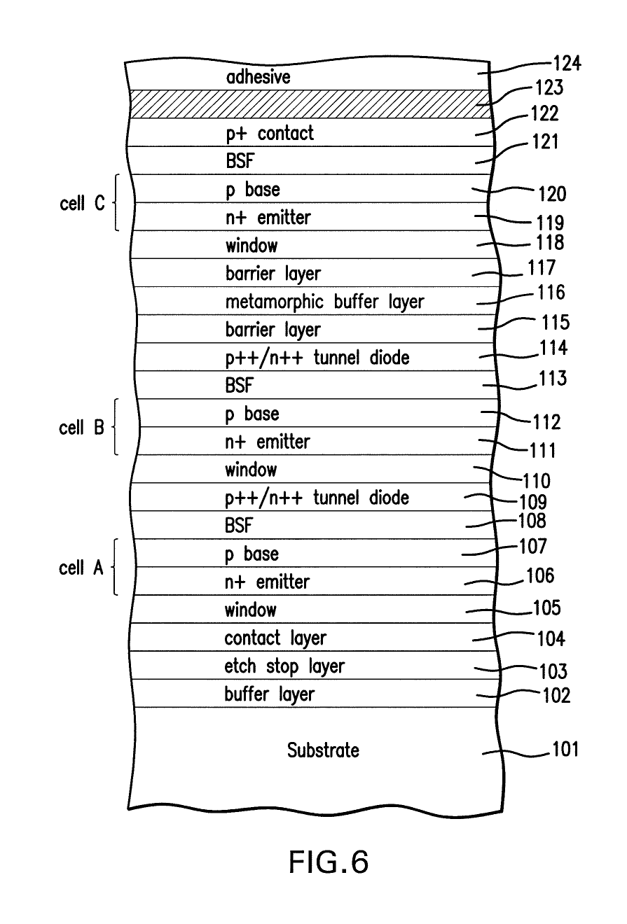

FIG. 6 is a cross-sectional view of the solar cell of FIG. 5 after the next process step in which an adhesive layer 124 is deposited over the metal layer 123. The adhesive is preferably Wafer Bond (manufactured by Brewer Science, Inc. of Rolla, Mo.).

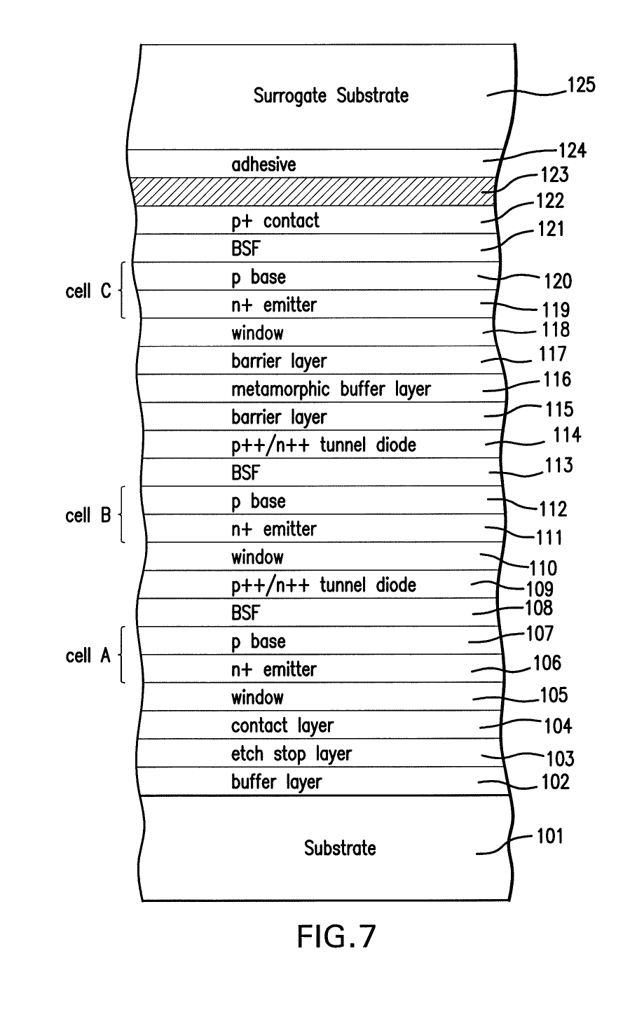

FIG. 7 is a cross-sectional view of the solar cell of FIG. 6 after the next process step in which a surrogate substrate 125, preferably sapphire, is attached. Alternatively, the surrogate substrate may be GaAs, Ge or Si, or other suitable material. The surrogate substrate is about 40 mils in thickness, and is perforated with holes about 1 mm in diameter, spaced 4 mm apart, to aid in subsequent removal of the adhesive and the substrate. As an alternative to using an adhesive layer 124, a suitable substrate (e.g., GaAs) may be eutectically bonded to the metal layer 123.

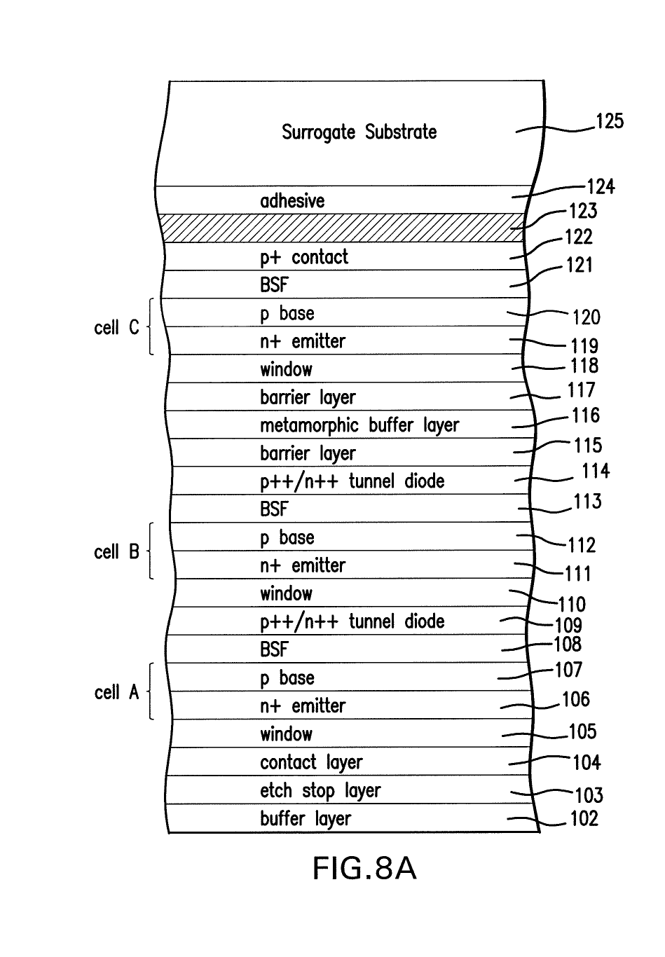

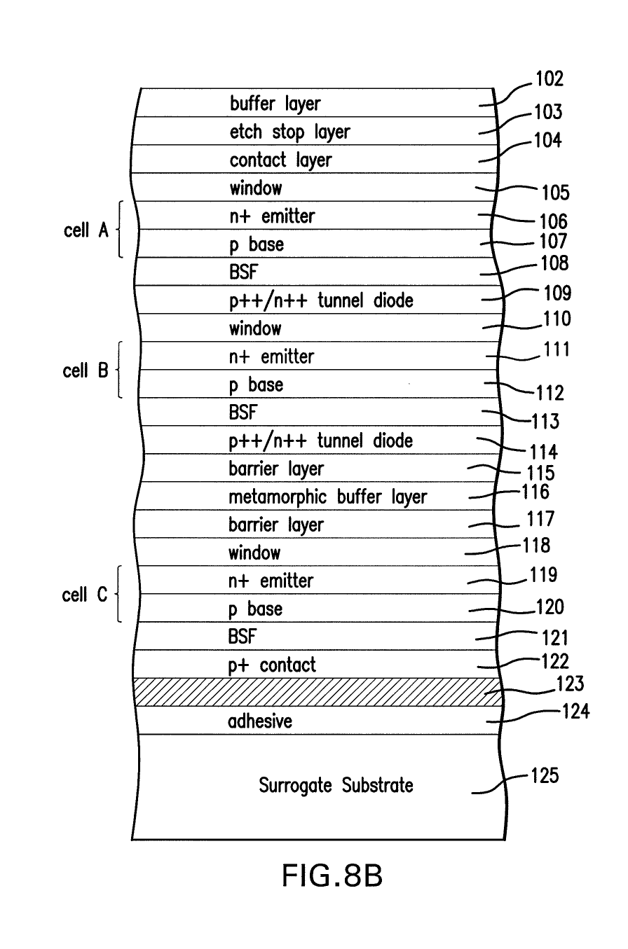

FIG. 8A is a cross-sectional view of the solar cell of FIG. 7 after the next process step in which the original substrate is removed by a sequence of lapping and/or etching steps in which the substrate 101, and the buffer layer 102, are removed. The choice of a particular etchant is growth substrate dependent.

FIG. 8B is a cross-sectional view of the solar cell of FIG. 8A with the orientation with the surrogate substrate 125 being at the bottom of the Figure. Subsequent Figures in this application will assume such orientation.

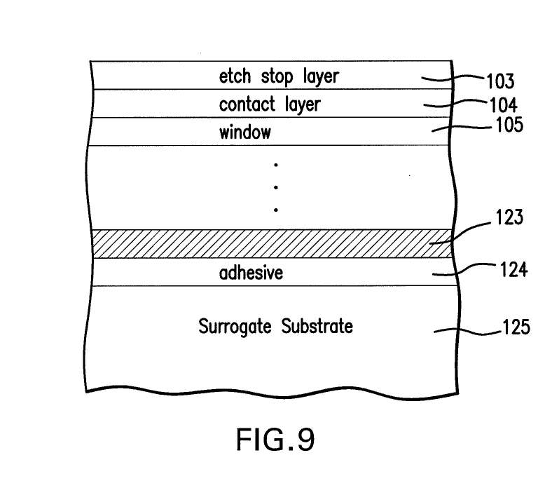

FIG. 9 is a simplified cross-sectional view of the solar cell of FIG. 8B depicting just a few of the top layers and lower layers over the surrogate substrate 125.

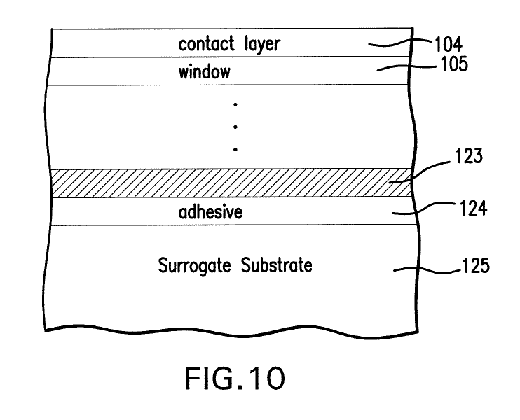

FIG. 10 is a cross-sectional view of the solar cell of FIG. 9 after the next process step in which the etch stop layer 103 is removed by a HCl/H₂O solution.

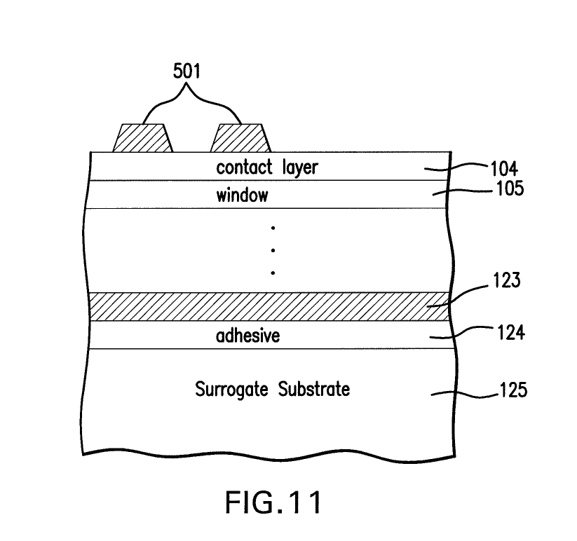

FIG. 11 is a cross-sectional view of the solar cell of FIG. 10 after the next sequence of process steps in which a photoresist mask (not shown) is placed over the contact layer 104 to form the grid lines 501. The grid lines 501 are deposited via evaporation and lithographically patterned and deposited over the contact layer 104. The mask is lifted off to form the metal grid lines 501.

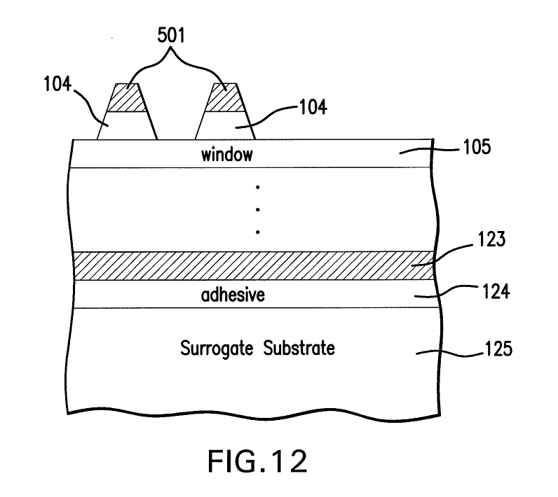

FIG. 12 is a cross-sectional view of the solar cell of FIG. 11 after the next process step in which the grid lines are used as a mask to etch down the surface to the window layer 105 using a citric acid/peroxide etching mixture.

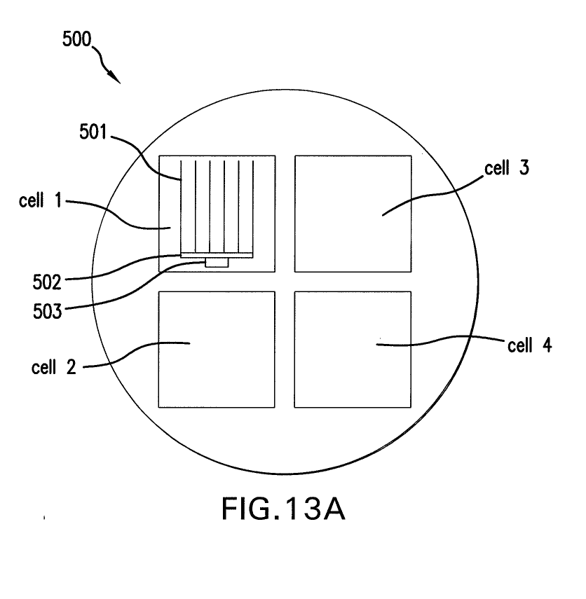

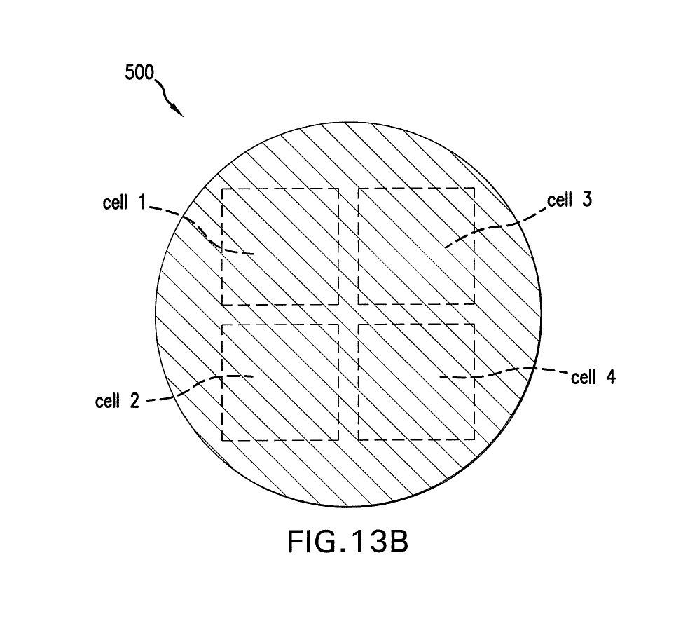

FIG. 13A is a top plan view of a wafer in which for solar cells are implemented. The depiction of four cells is for illustration for purposes only, and the present invention is not limited to any specific number of cells per wafer.

In each cell there are grid lines 501 (more particularly shown in cross-section in FIG. 12), an interconnecting bus line 502, and a contact pad 503. The geometry and number of grid and bus lines is illustrative and the present invention is not limited to the illustrated embodiment.

FIG. 13B is a bottom plan view of the wafer with four solar cells shown in FIG. 13A.

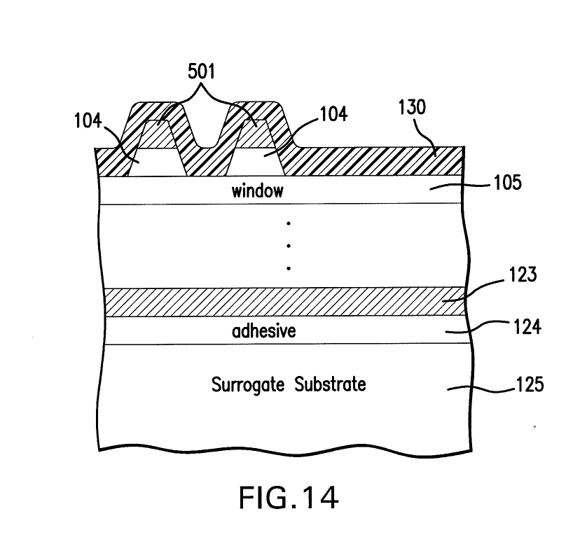

FIG. 14 is a cross-sectional view of the solar cell of FIG. 12 after the next process step in which an antireflective (ARC) dielectric coating layer 130 is applied over the entire surface of the “bottom” side of the wafer with the grid lines 501.

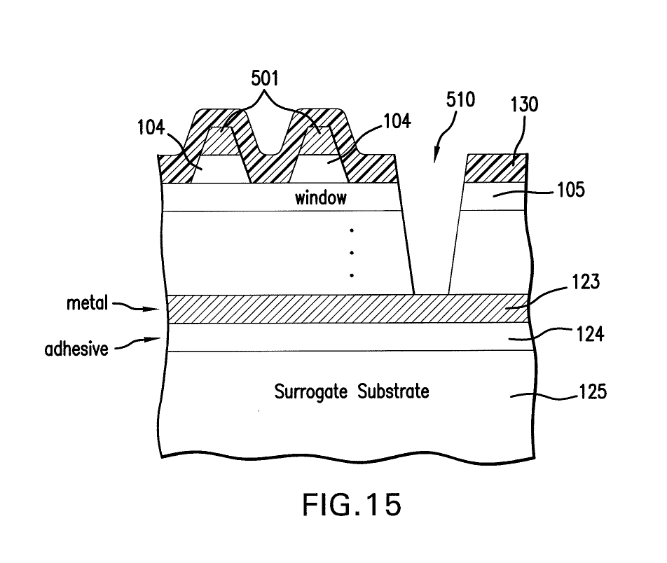

FIG. 15 is a cross-sectional view of the solar cell of FIG. 14 after the next process step according to the present invention in which a channel 510 or portion of the semiconductor structure is etched down to the metal layer 123 using phosphide and arsenide etchants defining a peripheral boundary and leaving a mesa structure which constitutes the solar cell. The cross-section depicted in FIG. 15 is that as seen from the A-A plane shown in FIG. 16.

FIG. 16 is a top plan view of the wafer of FIG. 15 depicting the channel 510 etched around the periphery of each cell using phosphide and arsenide etchants.

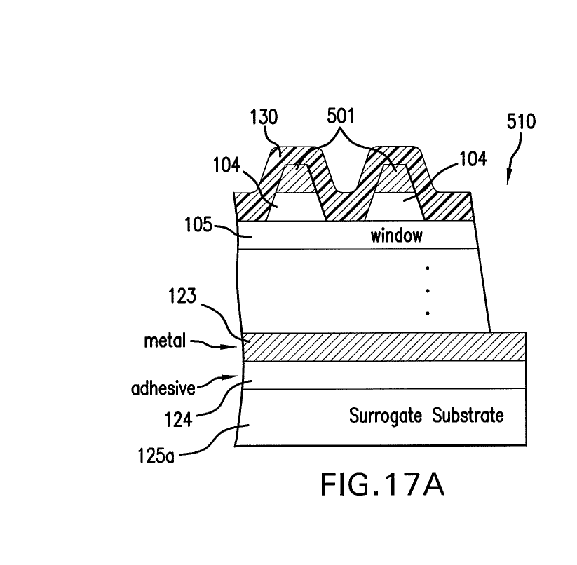

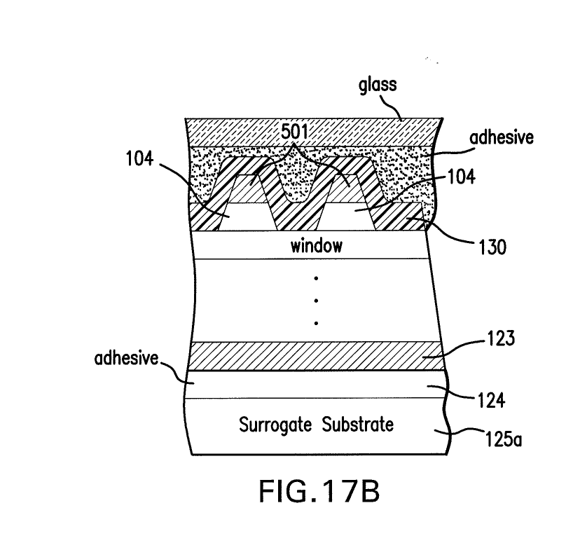

FIG. 17A is a cross-sectional view of the solar cell of FIG. 15 after the next process step in a first embodiment of the present invention in which the surrogate substrate 125 is appropriately thinned to a relatively thin layer 125a, by grinding, lapping, or etching.

FIG. 17B is a cross-sectional view of the solar cell of FIG. 15 after the next process step in a second embodiment of the present invention in which a cover glass is secured to the top of the cell by an adhesive.

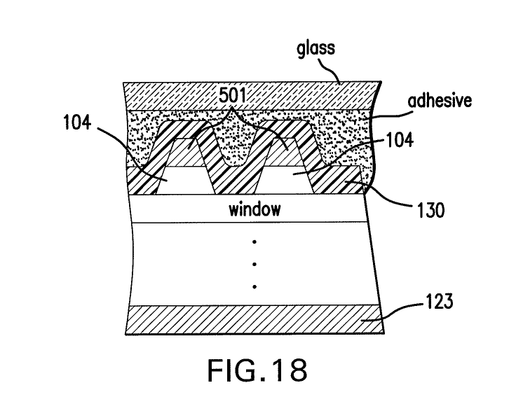

FIG. 18 is a cross-sectional view of the solar cell of FIG. 14B after the next process step in a third embodiment of the present invention in which a cover glass is secured to the top of the cell and the surrogate substrate 125 is entirely removed, leaving only the metal contact layer 123 which forms the backside contact of the solar cell. The surrogate substrate may be reused in subsequent wafer processing operations.

FIG. 19 is a graph of a doping profile in the emitter and base layers in one or more subcells of the inverted metamorphic multifunction solar cell of the present invention. The various doping profiles within the scope of the present invention, and the advantages of such doping profiles are more particularly described in copending U.S. patent application Ser. No. 11/956,069 filed Dec. 13, 2007, herein incorporated by reference. The doping profiles depicted herein are merely illustrative, and other more complex profiles may be utilized as would be apparent to those skilled in the art without departing from the scope of the present invention.

Although any off-cut angle between 6° and 20° is contemplated by the present invention, the provision of a 15° off-cut substrate 101 results in the metamorphic layer 116 exhibiting significantly better morphology than the metamorphic layers of previously known inverted metamorphic solar cells. An off-cut angle of the substrate 101 of 15° presents a higher density of growth nucleation sites (terraces), which encourages two-dimensional step flow growth under the growth conditions contemplated in the present invention. The higher off-cut surface orientation also causes the growth surfaces to be intersected more frequently by the (100) plane. These intersections, known as growth steps, act as nucleation points for growth islands. The higher density of nucleation points reduces the average atomic mobility required for atoms to reach a growth island, and encourages the growth islands to coalesce prior to the next layer growth, giving rise to two-dimensional growth. Layer-by-layer growth results in the best surface morphology.

It will be apparent that the choice of exactly a 15° off-cut is a function of cell structure and growth conditions in the solar cells fabricated. Indeed, an off-cut of 6° does provide an improved morphology compared with known multifunction solar cells. It is expected, moreover, that, for a predetermined set of growth conditions (growth temperature, growth rate, and the III to V ratio), there will be a different preferred off-cut surface orientation angle which optimises the surface morphology of the solar cell.

Although other off-cut orientations have some advantages over prior art multijunction solar cells, for all growth conditions investigated, the surface morphology is best in terms of fewer point defects and cross-hatch amplitude for a substrate having a 15° off-cut. Moreover, in addition to its impact on surface morphology, a 15° off-cut substrate has demonstrated other advantages, namely:

(i) it permits lower growth temperatures, significantly reducing the thermal budget of the lattice-matched subcells;

(ii) it increases the band gap of the InGaP subcell, by further disordering the group III sublattice; and

(iii) it reduces the Al content in the In GaAlP required to achieve a higher band gap value.

It will be understood that each of the elements described above, or two or more together, also may find a useful application in other types of constructions differing from the types of constructions described above.

Although the preferred embodiment of the present invention utilizes a vertical stack of three subcells, the present invention can apply to stacks with fewer or greater number of subcells, i.e. two junction cells, four junction cells, five junction cells, etc. In the case of four or more junction cells, the use of more than one metamorphic grading interlayer may also be utilized.

In addition, although the present embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present invention may utilize an arrangement of one or more, or all, homojunction cells or subcells, i.e. a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type InGaP is one example of a homojunction subcell. Alternatively, as more particularly described in U.S. patent application Ser. No. 12/023,772 filed Jan. 31, 2008, the present invention may utilize one or more, or all, heterojunction cells or subcells, i.e., a cell or subcell in which the p-n junction is formed between a p-type semiconductor and an n-type semiconductor having different chemical compositions of the semiconductor material in the n-type and n-type regions, and/or different band gap energies in the p-type regions, in addition to utilizing different dopant species and type in the p-type and n-type regions that form the p-junction.

The composition of the window or BSF layers may utilize other semiconductor compounds, subject to lattice constant and band gap requirements, and may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AIN, GaN, InN, GaInN, AlGaInN, GaInNAs, AlGaInNAs, ZnSSe, CdSSe, and similar materials, and still fall within the spirit of the present invention.

While the invention has been illustrated and described as embodied in a inverted metamorphic multijunction solar cell, it is not intended to be limited to the details shown, since various modifications and structural changes may be made without departing in any way from the spirit of the present invention.

Thus, while the description of this invention has focused primarily on solar cells or photovoltaic devices persons skilled in the art know that other optoelectronic devices, such as, thermophotovoltaic (TPV) cells, photodetectors and light-emitting diodes (LEDS) are very similar in structure, physics, and materials to photovoltaic devices with some minor variations in doping and the life minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

It will be understood that each of the elements described above, or two or more together, also may find a useful application in other types of constructions differing from the types of constructions differing from the types described above.

While the invention has been illustrated and described as embodied in a inverted metamorphic multifunction solar cell, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of manufacturing a solar cell comprising:
providing a first semiconductor substrate which is off-cut from the (001) crystal plane by at least 6° towards the (111)A plane;
forming a first subcell on said substrate comprising a first semiconductor material with a first band gap and a first lattice constant;
forming a second subcell comprising a second semiconductor material with a second band gap and a second lattice constant, wherein the second band gap is less than the first band gap and the second lattice constant is greater than the first lattice constant; and
forming a lattice constant transition material positioned between the first subcell and the second subcell said lattice constant transition material having a lattice constant that changes gradually from the first lattice constant to the second lattice constant.

2. A method as defined in claim 1, wherein said transition material is composed of any of the As, P, N, Sb based III-V compound semiconductors subject to the constraints of having the in-plane lattice parameter greater or equal to that of the first subcell and less than or equal to that of the second subcell, and having a band gap energy greater than that of the second subcell.

3. A method as defined in claim 1 wherein the transition material is composed of (InₓGa₁₋ₓ)_{y}Al_{1-y}As, with x and y selected such that the band gap of the interlayer remains constant at approximately 1.50 eV.

4. A method as defined in claim 1, wherein said first subcell is composed of an GaInP, GaAs, GaInAs, GaAsSb, or GaInAsN emitter region and an GaAs, GaInAs, GaAsSb, or GaInAsN base region.

5. A method as defined in claim 1, wherein the second subcell is composed of an InGaAs base and emitter regions.

6. A method of forming a multifunction solar cell comprising an upper subcell, a middle subcell, and a lower subcell, the method comprising:
providing a first substrate for the epitaxial growth of semiconductor material which is off-cut from the (001) plane by at least 6° towards the (111)A plane;
forming an upper first solar subcell on said off-cut substrate having a first band gap;
forming a middle second solar subcell over said first solar subcell having a second band gap smaller than said first band gap;
forming a graded interlayer over said second solar cell; and
forming a lower third solar subcell over said grading interlayer having a fourth band gap smaller than said second band gap such that said third subcell is lattice mismatched with respect to said second subcell.

7. The method as defined in claim 6, wherein the graded interlayer has a third band gap greater than said second band gap.

8. The method as defined in claim 6, wherein said graded interlayer is compositionally graded to lattice match the middle subcell on one side and the lower subcell on the other side.

9. A method as defined in claim 1, wherein said transition material is composed of any of the As, P, N, Sb based III-V compound semiconductors subject to the constraints of having the in-plane lattice parameter greater or equal to that of the middle subcell and less than or equal to that of the bottom subcell, and having a band gap energy greater than that of the middle subcell.

10. A method as defined in claim 1 wherein the transition material is composed of (InₓGa₁₋ₓ)_{y}Al_{1-y}As, with x and y selected such that the band gap of the interlayer remains constant at approximately 1.50 eV.

11. A method as defined in claim 1, wherein said first subcell is composed of an GaInP, GaAs, GaInAs, GaAsSb, or GaInAsN emitter region and an GaAs, GaInAs, GaAsSb, or GaInAsN base region.

12. The method as defined in claim 6, wherein the first substrate is composed of GaAs.

13. The method as defined in claim 6, wherein the off-cut angle is approximately 15°.

14. A method as defined in claim 6, further comprising depositing a contact layer over said third solar subcell and making electrical contact therewith.

15. A method as defined in claim 14, further comprising attaching a surrogate second substrate over said contact layer and removing said first substrate.

16. A method as defined in claim 9, further comprising:
patterning said contact layer into a grid; and

17. A method as defined in claim 15, further comprising thinning said surrogate second substrate

18. A method as defined in claim 15, further comprising mounting the solar cell on a support, and removing the surrogate substrate.

19. A method as defined in claim 18, wherein the support is a rigid coverglass.

20. A method of manufacturing a solar cell comprising:
providing a first semiconductor substrate which is off-cut from a crystal plane by at least 6° towards the (111)A plane:
forming a top subcell on said substrate and lattice matched therewith having a band gap in the range of 1.8 to 2.1 eV;
forming a middle subcell over said top subcell and lattice matched therewith, having a band gap in the range of 1.2 to 1.8 eV; and
forming a bottom subcell over said middle subcell and lattice mismatched therewith, having a band gap in the range of 0.7 to 1.2 eV.

21. The method as defined in claim 20, wherein the top subcell is composed of InGa(Al)P.

22. The method as defined in claim 20, wherein said middle cell is composed of a GaInP, GaAs. GaInAs, GaAsSb, or GaInAsN emitter region and a GaAs, GaInAs, GaAsSb, or GaInAsN base region.

23. The method as defined in claim 22, wherein the middle subcell is composed of an InGaP emitter layer and a GaAs or an In_{0.015}GaAs base layer.

24. The method as defined in claim 20, wherein the bottom subcell is composed of InGaAs base and emitter regions.

25. A method as defined in claim 20, further comprising a graded interlayer disposed between said middle subcell and said bottom subcell, said interlayer being compositionally graded to lattice match the middle subcell on one side and the bottom subcell on the other side.

26. The method as defined in claim 25, wherein said graded interlayer is composed of any of any of the As, P, N, Sb based III-V compound semiconductors subject to the constraints of having the in-plane lattice parameter greater or equal to that of the middle subcell and less than or equal to that of the bottom subcell, and having a band gap energy greater than that of the middle subcell.

27. The method as defined in claim 25, wherein the graded interlayer is composed of (InₓGa₁₋ₓ)_{y}Al_{1-y}As, with x and y selected such that the band gap of the interlayer remains constant at approximately 1.50 eV.

28. A method of forming a multijunction solar cell comprising:
providing a first semiconductor substrate which is off-cut from the (001) crystal plane by at least 6° towards the (111)A plane; and
forming a first top subcell including base and emitter layers composed of InGaP or InGa(Al)P semiconductor material, respectively, on said first substrate.

29. A method as defined in claim 28, further comprising;
forming a second subcell formed of GaAs semiconductor material over said first subcell.

30. A method as defined in claim 29, further comprising:
forming a third bottom subcell over said second subcell and lattice mismatched therewith.

31. A method as defined in claim 30, further comprising:
forming a lattice constant transition material positioned between the second subcell and the third subcell, said lattice constant transition material having a lattice constant that changes gradually from the lattice constant of the second subcell to the lattice constant of the third subcell.
a grading interlayer disposed over said second solar subcells and having a third band gap greater than said second band gap; and
a third solar subcell disposed over said grading interlayer that is lattice mismatched with respect to said middle subcell and having a fourth band gap smaller than said third band gap.

32. A solar cell as defined in claim 28, wherein said substrate is off-cut by 15° towards the (111)A plane.

33. A solar cell as defined in claim 28, wherein said substrate is selected from the group consisting of germanium or GaAs.

34. A solar cell as defined in claim 15, wherein said first solar subcell is composed of an InGa(Al)P emitter region and an InGa(Al)P base region.

35. A solar cell as defined in claim 15, wherein said second solar subcell is composed of an InGaP emitter region and an In_{0.015}GaAs or GaAs base region.

36. A solar cell as defined in claim 15, wherein said third solar subcell is composed of an InGaAs emitter layer and an InGaAs base layer.

37. A photovoltaic solar cell comprising:
top subcell including base and emitter layers composed of InGaP or InGa(Al)P semiconductor material, grown on a GaAs substrate having an off-cut from the (001) plane by at least 6° in the direction of the (111)A plane.

38. A solar cell as defined in claim 21, further comprising a bottom subcell disposed over a substrate selected from the group of GaAs, Ge, Si, or sapphire.

39. A solar cell as defined in claim 22, wherein said bottom subcell is bonded to said substrate by an adhesive.

40. A solar cell as defined in claim 22, wherein the bottom subcell is eutectically bonded to GaAs, Ge, or Si substrate.

41. A solar cell as defined in claim 21, further comprising a middle subcell composed of GaAs.

42. A solar cell as defined in claim 22, wherein a middle solar subcell disposed between said topcell and said bottom cell is composed of an InGaP emitter region and an In_{0.015}GaAs or GaAs base region.

43. A solar cell as defined in claim 22, wherein said bottom subcell is composed of an InGaAs emitter layer and an InGaAs base layer.

44. A solar cell as defined in claim 21, wherein said top subcell has a first band gap; and further comprising a second subcell over said first solar subcell having a second band gap smaller than said first band gap; a grading interlayer over said second solar cell, said grading interlayer having a third band gap greater than said second band gap; and a third solar subcell over said grading interlayer having a fourth band gap smaller than said second band gap such that said third subcell is lattice mismatched with respect to said second subcell.
